(19) United States
(12) Patent Application Publication
(10) Pub. No.: US 2003/0217689 A1
(43) Pub. Date: Nov. 27, 2003

(54) Method of producing crystal and apparatus for producing crystal

(75) Inventor: Masayoshi Asami, Chiba (JP)

Correspondence Address: FITZPATRICK CELLA HARPER & SCINTO, 30 ROCKEFELLER PLAZA, NEW YORK, NY, 10112, US

(73) Assignee: Canon Kabushiki Kaisha, Tokyo (JP)

(21) Appl. No.: 10/442,144

(22) Filed: May 21, 2003

(30) Foreign Application Priority Data
May 27, 2002 (JP) 2002-152472

(51) Int. Cl. C30B 9/00; C30B 11/00; C30B 17/00; C30B 21/02

(52) U.S. Cl. 117/81; 117/204; 117/200; 117/83

(57) ABSTRACT

An apparatus and method for producing a crystal with face-orientation control using a seed crystal being securely performed, and which can advantageously produce a high quality crystal with a large diameter quickly. A crystal-growth crucible movable in the vertical direction is used. While the temperature is being raised, the crucible is kept at a position where all the raw material, i.e., a crystalline substance placed in the crucible, is not melted. After the temperature stabilizes, the crucible moves in a first direction where the temperature becomes higher, so that the whole raw material and a part of the seed crystal melt. Then, the crucible moves in a second direction where the temperature becomes lower, whereby the seed crystal and the molten raw material sufficiently contact each other.

### BACKGROUND OF THE INVENTION

1. Field of the Invention

The present invention relates to an apparatus for producing a crystal using a crucible, and a method of producing a crystal using the apparatus. More particularly, the present invention relates to an apparatus for producing a fluoride crystal which is used in a wide wavelength range extending from the vacuum ultraviolet ray region to the far infrared radiation region, and is employed for an optical element with a large aperture (an aperture of 250 mm or more) or the like. The present invention also relates to a method of producing a crystal using the apparatus.

2. Description of the Related Art

Referring to crystalline materials for use in optical elements, according to a conventional known crystal production method, the crystal orientations are controlled, or single crystals are formed to enhance the uniformities of optical properties such as transmittance, refractivity, or the like. Thereafter, the crystalline materials are used as optical materials. For the production of crystals, methods in which crystals are formed in crucibles are employed, in addition to pulling-up methods not using crucibles, such as, typically, a Czochralski method.

Excimer laser oscillators using KrF, ArF, and F₂ as laser gas oscillate laser beams having wavelengths of 248 nm, 193 nm, and 157 nm, which are in the so-called ultraviolet ray wavelength range, respectively, and are used as light sources in semiconductor exposure devices in which high resolution optical projection is required. Optical systems using such laser beams must have a high transmittance in the above-mentioned wavelength ranges. As glass materials suitable for use in the optical systems, fluorides such as calcium fluoride, magnesium fluoride, barium fluoride, neodymium fluoride, lithium fluoride, lanthanum fluoride, and the like are known. Regarding these materials for use in optical elements, the crystal orientation thereof is controlled and single crystals are formed within crucibles, and thereafter, the crystals are worked into predetermined shapes and sizes. Thus, the optical elements are formed.

Hereinafter, one of the conventional methods of producing crystals using crucibles will be described, in which a calcium fluoride crystal (chemical stoichiometric ratio of CaF₂), which is called fluorite, is referred to as a typical example of the crystal.

FIG. 3 is a conceptual view of a conventional method of producing fluoride crystals such as calcium fluoride crystals or the like.

First, in process S1, powdery raw material is prepared, and the powdery raw material is placed in a vessel, and in process S2, is melted and then cooled. In process S3, the formed solid block is crushed by means of a crusher. The process S2 is carried out in order to reduce the difference between the bulk densities of the block before and after melting in process S4. Moreover, in the process S2, a scavenger is added to remove impurities from the raw material.

Thereafter, in the process S4, the crushed block pieces are placed in a crucible suitable for crystal growth, melted, and then, gradually cooled, whereby a crystal is made to grow. Thus, a fluorite crystal block is produced. In the process 4, first, a temperature distribution is generated inside of an apparatus for producing a crystal in such a manner that the inner upper part of the apparatus has a temperature equal to or higher than the melting point of the crystal to be grown, and the inner lower part thereof has a temperature lower than the melting point of the crystal. Subsequently, a crucible containing a raw material for the crystal therein is set in the inner upper part of the crystal-production apparatus, so that the raw material is melted to become a molten liquid. Thereafter, the crucible is gradually lowered into the inner lower part of the apparatus having a temperature set to be lower that the melting point of the crystal. Thus, the crystal is made to gradually grow in the direction from the lower part of the crucible toward the upper side.

The fluoride crystal block produced as described above is annealed, cut to a predetermined thickness, and worked or formed in a desired lens shape or the like. The product is used as an optical article.

However, ordinarily, the temperatures of apparatuses for growing crystals are controlled by control methods such as PID (Proportional-Integral-Differential) method and the like. In this case, for the temperature control, a predetermined temperature distribution including the melting point of a crystal to be grown is generated inside of an apparatus for growing a crystal. In the control of the temperature of the apparatus by the above-described method, especially, in the initial heating, that is, in heating from a room temperature to a predetermined temperature, a so-called “overshoot” phenomenon readily occurs, in which the apparatus is overheated so as to exceed the predetermined temperature and then is stabilized at the predetermined temperature. The overheating degree, caused by the overshooting, tends to become higher with increasing of the heat capacity of a controlled material and also the heating rate in the initial heating.

To enhance the projection resolution of a semiconductor exposure device, it is effective to increase the sizes of optical elements constituting an optical system. Thus, it is demanded to produce crystals suitable for use in such optical elements having large apertures. To produce such crystals having large diameters as described above, a crystal production apparatus itself having a larger size must be employed. As a result, the heat capacity of the apparatus increases. Moreover, to enhance the production efficiency, it is desired to increase the heating rate in the initial heating process of crystal-growth so that the process can be performed in a short time.

For the above-described reasons, the overshoot occurring during the initial heating process in the apparatus for growing a crystal tends to be intensified.

Referring to the crystal-growth using a crucible, in many cases, a seed crystal is placed into the crucible, and the crystal is made to grow in such a manner that the orientation of the seed crystal can be succeeded. That is, so-called seeding is carried out.

However, if the above-described temperature-overshooting becomes excessive, the seed crystal inserted in the inner lower part of the crucible will also be melted caused by the overheating, and thus, seeding becomes impossible in some cases. Moreover, even if all of the seed crystal is not melted, the raw material, which contacts with the seed crystal and is melted at overheating, is immediately cooled at a relatively high rate so as to be solidified into a polycrystal. As a result, problems are caused in that the seed crystal does not get into contact with the molten raw material when the crystal-growth starts. Thus, seeding becomes impossible.

### SUMMARY OF THE INVENTION

In view of the foregoing, it is an object of the present invention to provide an apparatus for producing a crystal which is suitable for production of a crystal with a large diameter and having a controlled face-orientation, and to provide a method of producing a crystal, solving the above-described problems.

To achieve the above-described object, the present invention provides a method of growing a crystal which comprises the steps of: generating a predetermined temperature distribution including the melting point of a crystal to be grown in a crystal-growing furnace in the state in which, regarding a crucible having a raw material for the crystal to be grown and a seed crystal placed therein, the portion of the crucible having the seed crystal placed therein is held at a position in the crystal-growing furnace at which the temperature is lower than the melting point of the crystal; moving the crucible in a first direction relative to the temperature distribution after the temperature distribution is generated to melt the unmelted raw material for the crystal; and moving the crucible in a second direction relative to the temperature distribution to grow the crystal.

In yet another aspect, the present invention relates to a method of growing a crystal, the method comprising the steps of: (1) providing a crucible having placed therein (a) a raw material for a crystal to be grown in a crystal-growing furnace and (b) a seed crystal, (2) generating a predetermined temperature distribution in the crystal growing-furnace, the predetermined temperature distribution including the melting point of the crystal, in a state in which a portion, having the seed crystal placed therein, of the crucible is held at a position in the crystal-growing furnace at which the temperature is lower than the melting point, (3) moving the crucible in a first direction relative to the temperature distribution after the temperature distribution is generated to melt the unmelted raw material for the crystal, and (4) moving the crucible in a second direction relative to the temperature distribution to grow the crystal.

In a still further aspect, the present invention relates to a method of producing a crystal, the method comprising the steps of (1) moving a crucible, in a crystal-growing furnace having generated therein a temperature distribution including the melting point of a crystal to be grown, the crucible having placed therein a raw material for the crystal to be grown, relative to the temperature distribution to grow the crystal, (2) generating a uniform heat zone of which the temperature is lower than the melting point of the crystal and is substantially uniform, at least in a part of the inside of the crystal-growing furnace, after the crystal-growth is completed, (3) moving the crucible into the uniform heat zone, and (4) decreasing the temperature in the uniform heat zone substantially uniformly at a predetermined rate.

In yet another aspect, the present invention relates to an apparatus for producing a crystal, the apparatus comprising (a) a crucible in which a raw material for a crystal to be grown and a seed crystal are placed, (b) means for heating to generate a predetermined temperature distribution in the surroundings of the crucible, and (c) means for supporting and moving the crucible, wherein the supporting and moving means is movable in a first direction relative to the generated temperature distribution and in a second direction opposite to the first direction.

In a still further aspect, the present invention relates to a crystal produced according to any of the aforementioned methods.

In yet another aspect, the present invention relates to an optical element comprising the crystal.

In a still further aspect, the present invention relates to a semiconductor exposure device comprising the optical element, e.g., a semiconductor exposure device comprising (a) a wafer stage on which a wafer to be exposed is placed, (b) an optical illumination-system which guides a light from a light source to a reticle, and (c) an optical projection-system which guides the light transmitted through the reticle to the wafer on said wafer stage, wherein at least one of the optical illumination-system and the optical projection-system comprises at least the optical element according.

According to the apparatus for producing a crystal and the method of producing a crystal having the above-described constitution, the seed crystal and the molten raw material can securely contact each other. A fluoride crystal with a large diameter, and having a face-orientation controlled accurately in a short time, can be provided. Moreover, fluoride crystals having a high reliability can be produced.

Further objects, features and advantages of the present invention will become apparent from the following description of the preferred embodiments with reference to the attached drawings.

### BRIEF DESCRIPTION OF THE DRAWINGS

FIG. 1 is a schematic cross-sectional view of the crystal-growing furnace of an apparatus for producing a fluoride crystal according to a first embodiment of the present invention.

FIG. 2 is a schematic cross-sectional view of the crystal-growing furnace of an apparatus for producing a fluoride crystal according to a third embodiment of the present invention.

FIG. 3 is a conceptual view of a conventional process of producing a fluorite crystal.

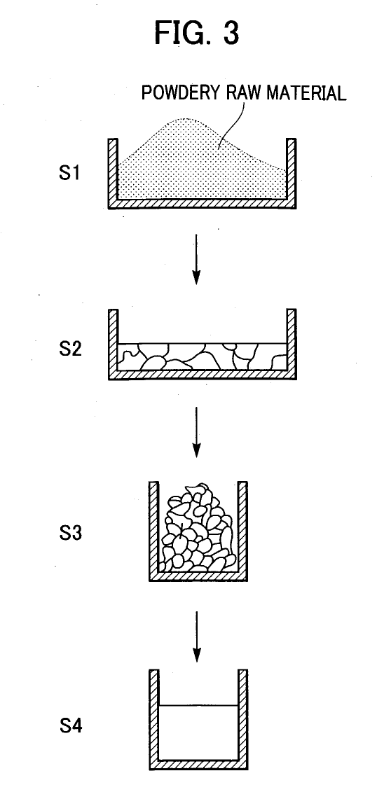

FIG. 4 shows an optical projection-system of an exposure device using an optical part produced according to the present invention.

FIG. 5 shows an example of an optical article for use in an exposure device according to the present invention.

FIG. 6A is a schematic view of an excimer laser oscillator using an optical part according to the present invention.

FIG. 6B is a schematic view of another excimer laser oscillator using an optical part according to the present invention.

FIG. 7 illustrates a method of growing a crystal according to the first embodiment of the present invention.

FIG. 8 illustrates a method of annealing a crystal after the crystal is grown using a crystal-growing furnace according to a second embodiment of the present invention.

FIGS. 9A, 9B, and 9C are schematic cross-sectional views of the crystal-growing furnace at each step of crystal growing process in the present invention.

### DESCRIPTION OF THE PREFERRED EMBODIMENTS

[First Embodiment]

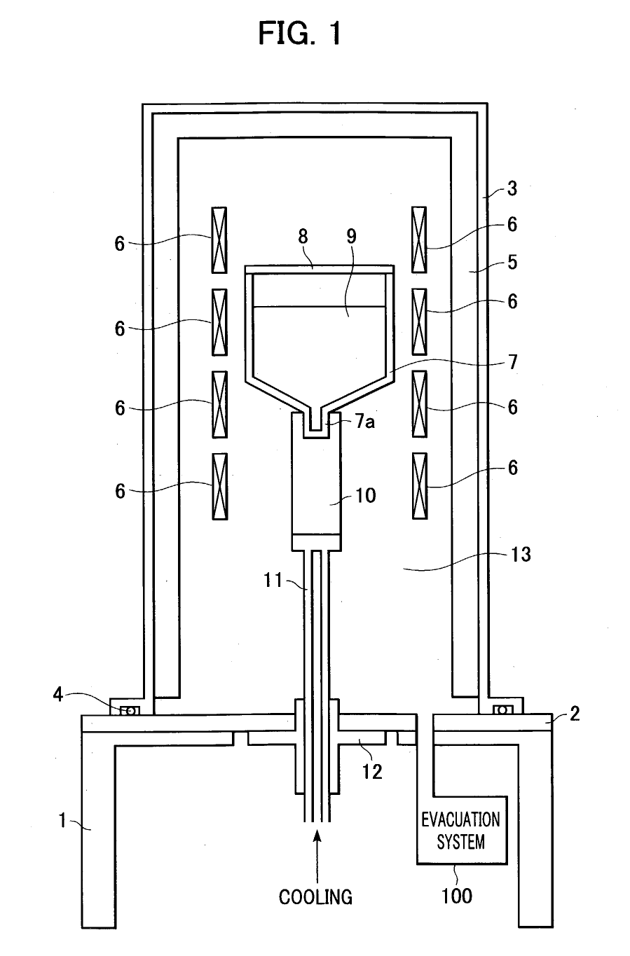

FIG. 1 shows a crystal-growing furnace of a apparatus for producing a crystal with a large diameter (at least 250 mm). Hereinafter, calcium fluoride (fluorite) will be described as an example of a crystal to be grown. It should be noted that the present invention is not restricted to a crystal having a diameter of at least 250 mm.

Referring to FIG. 1, a crystal-growing furnace 13 is formed on the upper side of a stand 1 and a base plate 2. In the furnace 13, a chamber 3 is sealed with an O-ring 4. An evacuation system 100 is connected to evacuate the inside of the crystal-growing furnace 13. A crucible 7 made of carbon, having a calcium fluoride raw material 9 placed therein, is set inside of the crystal-growing furnace 13. The crucible 7 is closed by a lid 8 made of carbon so that evaporation-off of the raw material calcium fluoride 9 is prevented. Moreover, cylindrical heaters 6 are arranged around the crucible 7 in the crystal-growing furnace 13 so that a predetermined temperature distribution can be generated in the crystal-growing furnace 13. A thermal insulating material 5 made of carbon is arranged inside of the chamber 3 to protect the chamber inner walls from radiation heat generated in the heaters 6.

The crucible 7 is connected to a supporting shaft 11 through a joint member 10 made of carbon. The supporting shaft 11 is cooled, and has such a structure that it can vertically move the crucible. When the crucible is moved, external leakage from the apparatus is prevented by a sealing member 12. Care must be taken when the supporting shaft 11 is raised during the manufacturing process in the evacuated crystal-growing furnace 13. In particular, a part of the supporting shaft 11 which has been exposed to the air enters the vacuum furnace. Therefore, oxygen which has been adsorbed to the surface of that part of the supporting shaft 11 diffuses in the furnace, when the supporting shaft 11 is raised at a relatively high speed for the performance of the evacuation system 100. Thus, there is a danger in that the crystal is oxidized. For this reason, in the evacuation system 100 of this apparatus, the opening for the crystal-forming furnace 13 is provided near the supporting shaft. In addition, the evacuation system 100 is used in conjunction with a limited raising speed, that is, at a speed of up to about 10 mm/h.

Hereinafter, a method of growing a crystal by use of the apparatus of the present invention will be described in detail. In the process of growing a crystal, first, refined calcium fluoride 9 is placed into the crucible 7 for the crystal-growing furnace 13. Preferably, the size (diameter) of calcium fluoride produced in the purified process described in the conventional example is 0.9 to 0.95 times of the size (diameter) of the crucible of the crystal-growing furnace. In other words, it is preferred that the ratio of the size (diameter) of the fluoride compound produced in a crucible for a refining furnace to the size (diameter) of the crucible for the crystal-growing furnace is in the range of from 1:1.05 to 1:1.1. This is because the fluoride compound crystal taken out from the crucible for the refining furnace can be placed into the crucible for the crystal-growing furnace without the crystal being crushed.

Also, in the process of growing a crystal, a scavenger may be added to the crystal-growth crucible together with calcium fluoride, in order to remove calcium oxide.

The crucible 7 according to the first embodiment is provided with a space 7a for setting a seed crystal. A cylindrical seed crystal having a desired face-orientation in the section thereof is placed into the space 7a in advance, and seeding is carried out for a crystal to be grown. Thereby, a single crystal having a desired crystal orientation can be made to grow.

As described above, the seed crystal and the calcium fluoride raw material are placed into the crucible 7, and the crucible 7 is set in the crystal-growing furnace 13. Thereafter, the inside of the crystal-growing furnace 13 is evacuated to about 10⁻³ to 10⁻⁴ Pa (by the evaluation system 100). Thereafter, the heaters 6 are made to electrically conduct so as to generate a predetermined temperature distribution inside of the crystal-growing furnace 13. Thus, the calcium fluoride raw material 9 is melted. In the case where a crystal is made to grow using a raw material for the crystal as a starting material in the crucible, as shown in FIG. 1, the stable growth of the crystal can be performed by growing in the direction from the bottom of the crucible toward the upper side thereof. Accordingly, regarding the temperature on the inside of the crystal-growing furnace 13, the outputs of the heaters 6 are controlled so that a temperature gradient is caused, in which the temperature is higher at a higher position in the furnace, that is, the temperature is reduced at a lower position in the furnace. Preferably, the crystal is made to grow by gradually lowering the crucible 7 with respect to the temperature distribution.

The temperature on the upper side of the crucible and in the surroundings of the crucible is required to be equal to or higher than the melting point of calcium fluoride. Preferably, the temperature is in the range of 1390° C. to 1450° C. That is, if the temperature is 1380° C. or lower, it will take a relatively long time to completely melt the raw material. Thus, the production efficiency cannot be enhanced. Moreover, if the temperature is 1450° C. or higher, the calcium fluoride raw material will be vigorously gasified. This causes the production efficiency to decrease, due to the loss of the raw material. Furthermore, the seed crystal also may be melted.

As described above, the inside of the crystal-growing furnace 13 is gradually heated with the heaters 6 so that the temperature on the upper side and in the surroundings of the crucible is in the range of from 1390° C. to 1450° C. In this case, if a large production apparatus such as the crystal-growing furnace described in the first embodiment is used, intense overshoot will be caused after the temperature reaches a target value. Probably, one reason for this overshoot lies in that when the generally used PID method is used for the temperature control, the integration component exerts an influence. Moreover, in the case of a production apparatus having a large heat capacity, the overshoot may occur, since the time when heat is emitted from the heaters 6 becomes considerably different from the time when the heat is detected as a practical temperature rise. The overshoot degree can be reduced by decreasing the rate at which the temperature rises to a target value. However, problems are caused in that the production efficiency is deteriorated.

When the temperature is overshot as described above, the seed crystal 20 setting space 7a in the crucible 7 is overheated to be higher than a target value, although the temperature in the space 7a is originally maintained at a temperature lower than the melting point of calcium fluoride. Thus, in the seed crystal setting space 7a in the crucible 7, the seed crystal may be excessively melted or all the seed crystal 20 may be melted.

If all the seed crystal is melted, the seeding will be impossible. Thus, it is difficult to grow a single crystal having a desired crystal orientation. Moreover, even if all the seed crystal is not melted, the part of the crystal which is excessively melted is quickly solidified to be polycrystalline in the care that the overshoot is reduced so that the temperature reaches the original target value. As a result, the molten material cannot get into contact with the surface of the seed crystal. Thus, the seeding cannot be performed.

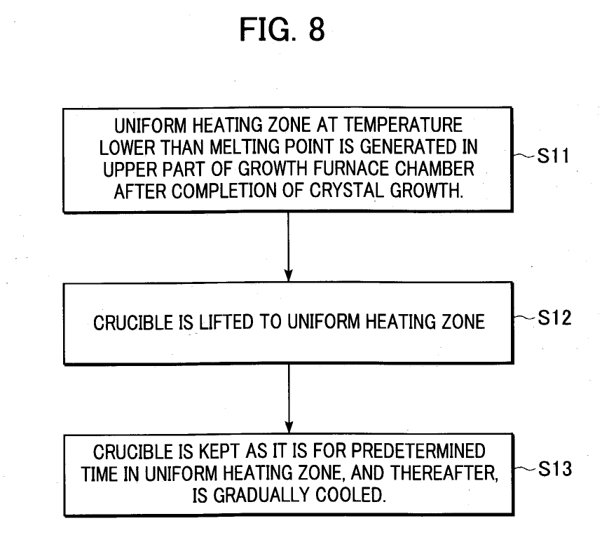

To solve the problems caused by the overshoot of the temperature at heating as described above, the crystal-growing furnace 13 described in the first embodiment has a mechanism in which the crucible 7 containing the raw material 9 therein can be lifted even during the manufacturing process. The crystal growth is carried out using the mechanism and the method illustrated in FIG. 7.

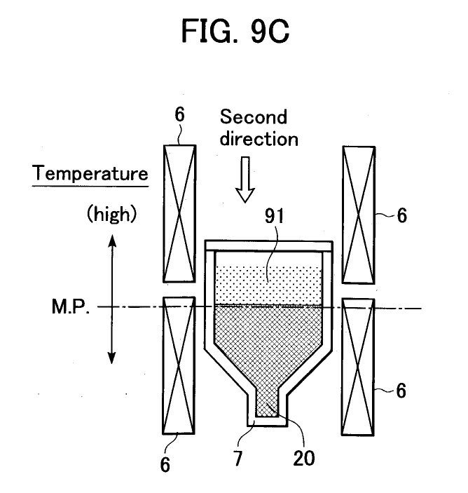

FIG. 9 shows the process sequence in this embodiment. In particular, in heating from room temperature, the crucible 7 is fixed at a position where the temperature of the bottom portion of the crucible having the seed crystal placed therein is relatively low (process S1). Thereby, the seed crystal and the calcium fluoride raw material 92 near the seed crystal remain unmelted (FIG. 9(a)), so that the seed crystal itself can be securely prevented from melting due to the overshoot. Thereafter, heating is carried out with the heaters 6 so that a predetermined temperature distribution is generated in the crystal-growing furnace, and a part of the raw material 91 for the crystal is melted (FIG. 9(a), process S2). After the overshoot caused by the heating is eliminated, the crucible 7 is lifted to a predetermined position by means of a mechanism with which the crucible 7 can be lifted (first movement)(FIG. 9(b), process S3). Thereby, after the temperature in the crystal-growing furnace 13 is stabilized at a target value, a part of the seed crystal is melted. Accordingly, the seed crystal and the molten raw material can get into direct contact with each other, and thus, satisfactory seeding can be performed (FIG. 9(b)). Moreover, after the first movement is carried out, and the temperature distribution and the position of the interface between the solid and liquid phases in the crucible 7 are stabilized, the crucible 7 is lowered at a predetermined rate so that the crystal is made to grow on the seed crystal (second movement)(FIG. 9(c), process S4).

Preferably, the first and second movements are carried out at such a low velocity that the movement can be taken as pseudo-static. The heat capacities of the raw material 9 and the crucible 7 are sufficiently small compared to the heat capacity of the whole crystal-growing furnace 13. Accordingly, the crucible 7 can be moved while the temperature distribution in the crystal-growing furnace 13 is prevented from change due to the pseudo-static movement. Thus, the crystal growth can be more stably performed.

In the first movement, preferably, about half of the seed crystal 20 placed in the seed crystal setting space 7a is melted. In brief, it is simply required that the seed crystal 20 and the raw material 9 melted in the crucible contact directly with each other. Therefore, preferably, the position to which the crucible is lifted by the first movement is determined while the position of the interface between the solid and liquid phases in the crucible is confirmed. To detect the detection of the interface, the position of the interface may be directly observed by using techniques such as ultrasonic searching, acoustic emission, or the like. Moreover, conveniently, a thermocouple may be disposed on the lower side of the crucible 7, extended through the supporting shaft 11. The thermocouple may be used to obtain a reference for the interface position. In particular, to determine the conditions, a cut-marked seed crystal is used, and the temperature in the furnace and the position of the crucible are changed. Thus, the temperature indicating values and the positions of the melting interface are recorded. When the first movement is carried out, the position of the melting interface can be anticipated using the temperature indicating values of the thermocouple as a reference.

Referring to the temperature in the crystal-growing furnace, the outputs of the heaters 6 are controlled so as to generate a temperature gradient in which the temperature becomes higher at a higher position in the furnace, that is, the temperature becomes lower at a lower position in the furnace. The crystal can be made to grow in the direction from the lower side of the seed crystal toward the upper side by the second movement in which the crucible is lowered.

The lowering speed of the crucible 7 in the second movement for crystal-growth is ordinarily in the range of 0.1 to 5.0 mm/h. If the speed is excessively low, the production efficiency will be deteriorated. If the speed is too high, the crystal will tend to become polycrystalline, since the temperature change is drastic. In the worst case, the crystal is cracked. The lowering velocity depends on the size of a crystal to be formed and a target crystal-quality. More preferably, for production of a crystal with a diameter of about 250 mm, the lowering velocity is in the range of about 0.5 to 2 mm/h.

In the second movement, all the melting liquid in the crucible 7 is solidified. Thus, the crystal growth is completed. As described above, the crucible 7 is moved after the temperature distribution is generated and becomes stable in the crystal-growing furnace 13, and seeding is carried out using the seed crystal. Accordingly, the face-orientation can be controlled irrespective of the heat capacity of the production apparatus and the temperature-rising rate.

[Second Embodiment]

After-processing to further enhance the qualities of a crystal using the apparatus, that is, the crystal-growing furnace 13 of FIG. 1, is carried out after the crystal is made to grow in the production apparatus of FIG. 1 as described in the first embodiment. Hereinafter, the after-processing will be described.

Ordinarily, the crystal having been made to grow as described in the first embodiment is cut and used. However, crystals developed using a temperature gradient as described above have large thermal strains inside thereof. The thermal strains become larger with the size of a grown crystal. The effects of the strains become remarkable. Therefore, in general, the grown crystal is annealed at a temperature lower than the melting point of the crystal so that the strain is removed, and thereafter, cutting work is carried out.

However, if the grown crystal is transferred to an annealing apparatus for exclusive-use and is heated to be annealed, the production efficiency will be reduced. Accordingly, it is convenient that the crystal can be annealed in the crystal-growing furnace at least to such a degree that the crystal is not cracked in the cutting and shaping work before polishing.

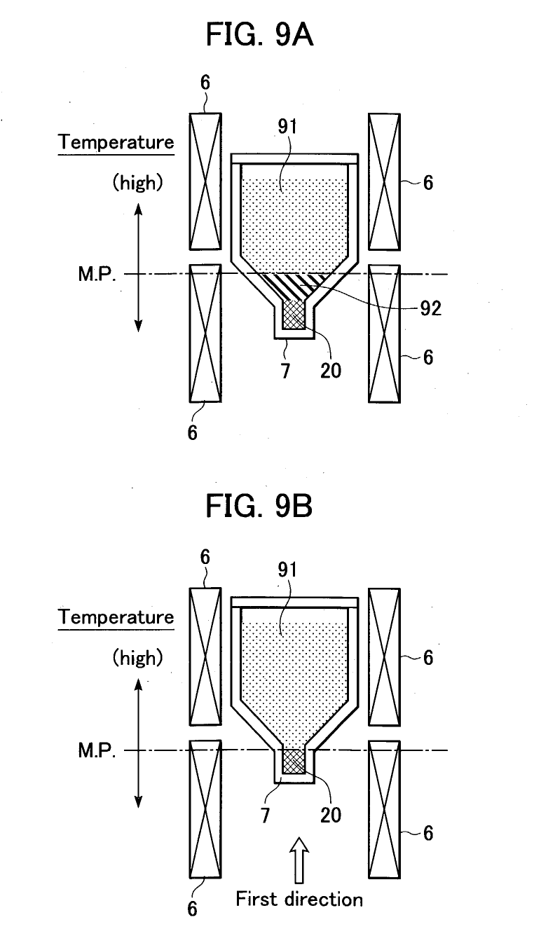

For this reason, efficiently, the crucible is lifted again in the crystal-growing furnace 13 in which a temperature distribution suitable for annealing is formed, by use of the mechanism provided in the crystal-growing furnace as described in the first embodiment, i.e. the mechanism enabling the crucible 7 to be lifted even during the manufacturing process. FIG. 8 illustrates a method of annealing a crystal after the growth is completed, utilizing the above-mentioned mechanism and the crystal-growing furnace. Hereinafter, an annealing process will be described, in which a crystal is annealed by use of the crystal-growing furnace 13 after the growth is completed.

When the crystal growth process is completed as described in the first embodiment, the crucible 7 has been moved to a position in the inner lower part of the crystal-growing furnace 13. At this time, in the inner upper part of the crystal-growing furnace 13, the temperature distribution is generated for the crystal growth, in which the temperature is higher than the melting point of the crystal.

In this state, the heaters 6 are operated so that the temperature distribution in the inner upper part of the crystal-growing furnace 13 has a predetermined temperature which is substantially uniform, which is lower than the melting point, and which is suitable for annealing (process S11). Subsequently, the crucible 7 is lifted to a zone having the above-mentioned temperature which is substantially uniform, by use of a lifting mechanism (process S12).

The crucible 7 lifted as described above is kept preferably at a temperature of about 900 to 1300° C. for about 20 hours so that strains are removed from the crystal, and then, is gradually cooled to a room temperature (process S13). Preferably, the cooling rate is in the range of 1° C./h to 10° C./h, depending on the size of the crystal.

[Third Embodiment]

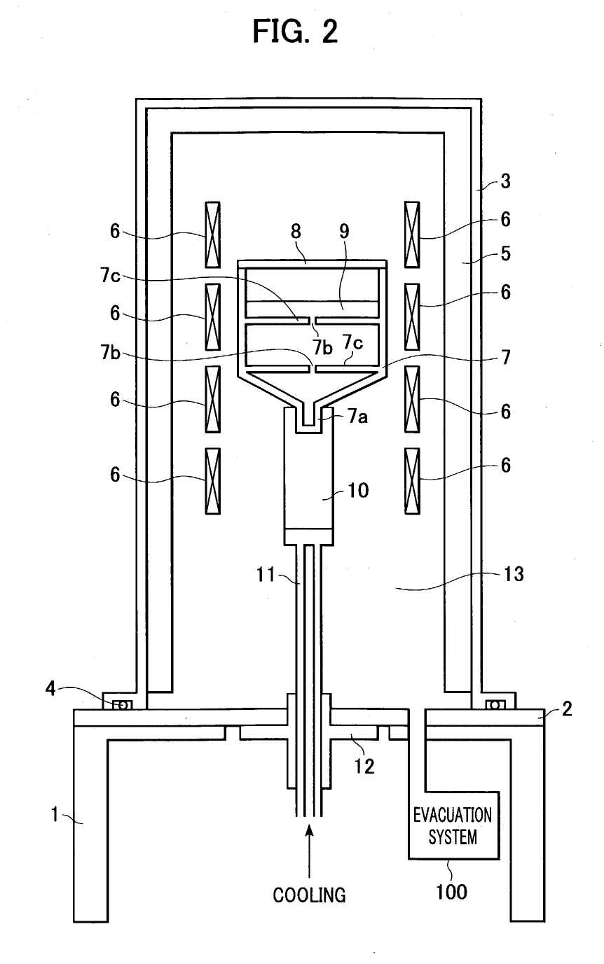

FIG. 2 shows an apparatus for producing a crystal according to a third embodiment of the present invention. The apparatus is the same as that of the first embodiment except that the inside of the crucible 7 is sectioned by partitioning plates 7c each having a connecting hole 7b in the center thereof. Other components are the same as the corresponding components of the first embodiment and are designated by the same reference numerals. Thus, description of the names and the functions is omitted.

In the case in which a crucible having the inner space partitioned as shown in FIG. 2 is used, and the size of each space is set to be substantially equal to the size of an optical element to be formed, the cutting work to be carried out after the growth of a crystal can be omitted. The yield of grown crystals is enhanced, and thus, expensive materials can be efficiently used. In addition, the practical size of a crystal to be grown can be reduced, and thus, advantageously, problems such as thermal strains or the like, which may be caused by the large sizes of crystals, can be solved.

When such a crucible 7 having the inner space partitioned as described above is used, a seed crystal is placed in the bottom portion of the crucible (i.e. space 7a), and a crushed calcium fluoride raw material 9 is placed into the respective spaces. At melting, the raw material placed as described above flows into the lower space through the connecting hole 7b to fill the voids between the crushed raw material pieces. In the apparatus for producing a crystal of FIG. 2, the temperature distribution is set in which the temperature is higher at a higher position in the crystal-growing furnace 13, that is, the temperature is more reduced at a lower position therein. Accordingly, first, the raw material positioned on the upper side is melted and flows into the lower space through the connecting hole 7b. At this time, the lower space has not been heated to a temperature higher than the melting point yet. When the melting liquid gets into contact with the seed crystal having a temperature kept to be lower than the melting point, the surface of the seed crystal is rapidly solidified, so that the surface is converted to be polycrystalline. Moreover, in some cases, gas-bubbles are formed due to the rapid solidification. If the crystal growth is started in this state, the seeding using the seed crystal cannot be performed, and a single crystal having a desirably controlled face-orientation cannot be obtained.

To solve the above-described problems, it is advantageous to use the crystal-growing furnace 13 described in the first embodiment and utilize the mechanism enabling the crucible 7 containing a raw material 9 therein to be lifted even during the manufacturing process. In particular, in heating from a room temperature, the crucible 7 is positioned so that the bottom portion of the crucible 7 having the seed crystal placed therein takes a position at which the temperature is relatively low. Thereby, the seed crystal and the calcium fluoride raw material in the vicinity of the seed crystal remain unmelted, and the seed crystal itself is securely prevented from melting due to the overshoot. It is estimated that the melting liquid flowing from the upper space causes the surface of the seed crystal to become polycrystalline. For this reason, the crucible 7 is lifted to a predetermined position by means of the mechanism enabling lifting of the crucible 7 after the temperature in the crystal-growing furnace 13 has a predetermined distribution (first movement). Thereby, the surface of the seed crystal converted to be crystalline and a part of the seed crystal are melted, so that the seed crystal and the molten raw material can directly get into contact with each other. Thus, the seeding can be satisfactorily performed. Moreover, the crucible 7 is lifted at a predetermined velocity so that the crystal is made to grow on the seed crystal (second movement) after the first movement is carried out and the temperature distribution and the position of the interface between the liquid and solid phases in the crucible 7 become stable.

When the production apparatus of the present invention is used, and the diameter of the crucible and the heights of the partitioned spaces are adjusted so as to correspond to a desired final shape and size, the cutting process can be omitted, and moreover, substantially no unused-materials are generated, which enhances the production efficiency.

The calcium fluoride of which the crystal is grown as described above is heat-treated in the annealing process. As described in the second embodiment, the annealing process may be carried out in the crystal-growing furnace 13 or another exclusive-use furnace which is different from the crystal-growing furnace. In the annealing process, the grown crystal is heated at a temperature of 900° C. to 1300° C. and is kept as it is (i.e. maintained) for a predetermined time to remove strains from the crystal. Preferably, the heating-keeping time is set at 20 hours or longer, depending on the size of the crystal and heat capacity. Thereafter, the temperature is gradually decreased to room temperature so that strains are suppressed from being introduced again into the crystal due to a temperature gradient generated by the cooling.

Thereafter, the crystal is shaped into an optical article having a desired shape and size (e.g., a convex lens, concave lens, disk-shape, plate-shape, or the like). An antireflection film is provided on the surface of the optical article, if necessary. Magnesium fluoride, aluminum oxide, and tantalum oxide are suitably used for the antireflection film. These can be formed by vapor deposition using resistance-heating, electron beam heating, sputtering, or the like.

[Fourth Embodiment]

An optical system especially suitable for excimer lasers, especially, ArF or F₂ excimer lasers can be formed by a combination of different type of lenses produced as described above. Furthermore, an exposure device can be formed by combination of an excimer laser light source, an optical system containing a lens made of calcium fluoride, and a stage which can move a substrate.

Hereinafter, an exposure device using an optical article according to the present invention will be described.

Examples of the exposure device include a reduction-projection exposure device using a lens-type optical system, and a lens-type equal-magnification exposure device.

Especially, to expose all the surface of a wafer, a stepper employing a step and repeat system is preferred, in which one of the small sections (fields) is exposed, and the wafer is moved by one step so that the next field is exposed. Needless to say, the lenses can be suitably used in an exposure device having a micro-scan system.

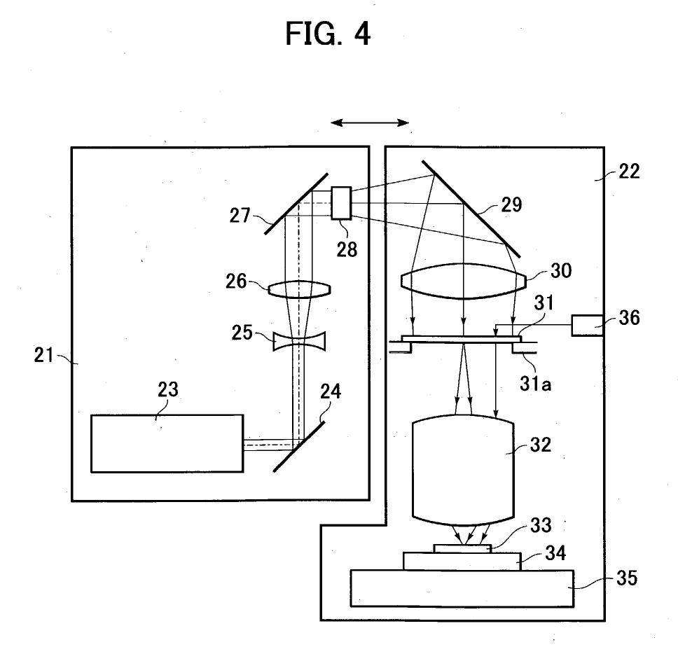

FIG. 4 schematically shows the configuration of the exposure device according to the present invention. In this drawing, an illumination light source unit 21 and an exposure-mechanism unit 22 are shown. The light source unit 21 and the exposure mechanism unit 22 are formed separately and independently of each other. That is, both are physically in the separated state. A light source 23 is a large-size light source having a high output such as an excimer laser or the like. Moreover, a mirror 24, a concave lens 25, and a convex lens 26 are shown. The lenses 25 and 26 function as beam-expanders and expand the size of a beam to be equal to the size of an optical integrator. A mirror 27 and an optical integrator 28 for uniformly illuminating a reticle from the upper side are shown. The illumination light source unit 21 comprises the laser 23, the mirror 24, the concave lens 25, the convex lens 26, the mirror 27, and the optical integrator 28. A mirror 29 and a condenser lens 30 (both of the exposure-mechanism 22) collimate a luminous flux emitted from the optical integrator 28. Furthermore, the exposure-mechanism 22 includes a reticle 31 having a circuit pattern drawn thereon, a reticle holder 31a which holds the reticle 31 by suction, an optical projection-system 32 for projecting the pattern of the reticle, and a wafer 33 on which the pattern of the reticle 31 is printed through the projection lens 32. An XY stage 34 holds the wafer 33 by suction, and is moved in the XY-direction when the wafer is printed by the step and repeat system. Reference numeral 35 designates a fixed plate of the exposure device.

The exposure mechanism unit 22 comprises the mirror 29, the condenser lens 30, the reticle 31, the reticle holder 31a, the optical projection-system 32, the wafer 33, the XY-stage 34, and the fixed plate 35. An alignment means 36 is used for TTL alignment. Ordinarily, the exposure device further contains an auto-focusing mechanism, a wafer-conveying mechanism, and so forth, which are included in the exposure-mechanism unit 22.

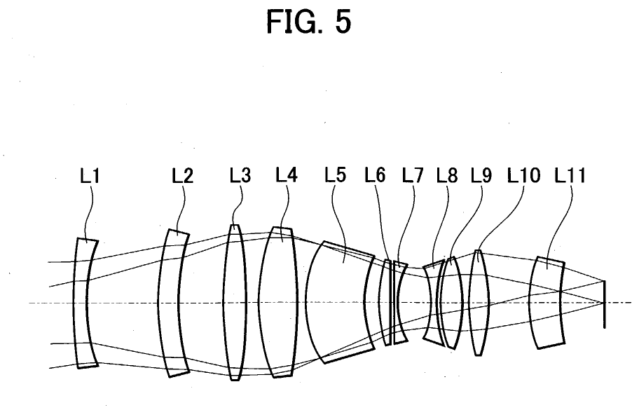

FIG. 5 shows an example of an optical article to be used in the exposure device of the present invention. The optical article comprises lenses to be used in the optical projection-system of the exposure device of FIG. 4. This lens assembly comprises eleven lenses, that is, lenses L1 to L11 which are combined without being bonded to each other. The optical articles made of fluorite according to the present invention are used as the lenses or mirrors shown in FIGS. 4 and 5 or as mirrors or lenses of a mirror type exposure device (not shown). More preferably, an antireflection film or reflection-increasing film is provided on the surface of a lens or mirror.

An optical part of the present invention may be uses as a prism or as etalons.

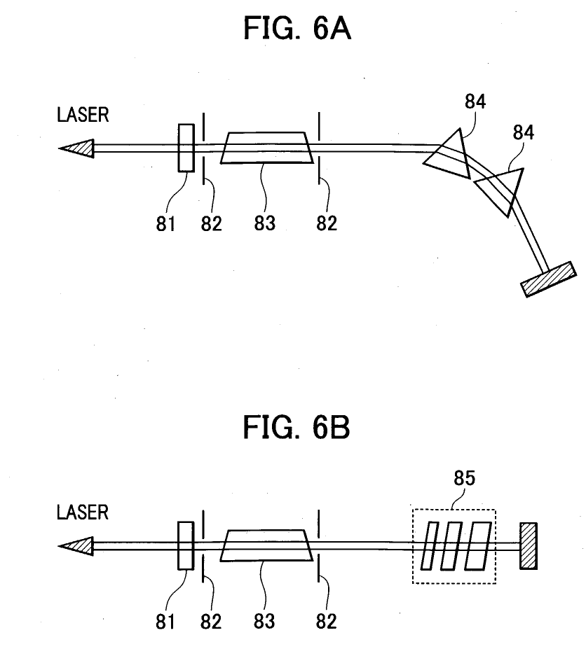

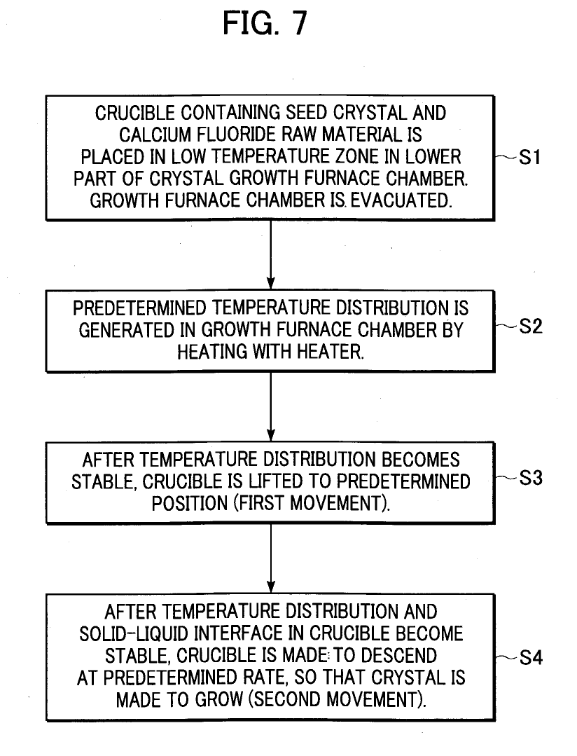

FIGS. 6A and 6B show the configurations of excimer laser oscillators each using optical parts made of calcium fluoride according to the present invention.

The excimer laser oscillator shown in FIG. 6A comprises a resonator 83 which emits an excimer laser and resonates, an aperture 82 for stopping the excimer laser emitted from the resonator 83, prisms 84 which convert the excimer laser to a single-line laser, and a reflection mirror 81 which reflects the excimer laser.

The excimer laser oscillator shown in FIG. 6B comprises a resonator 83 which emits excimer laser and resonates, an aperture 82 for stopping the excimer laser emitted from the resonator 83, etalons 85 which convert the excimer laser to a single-line laser, and a reflection mirror 81 which reflects the excimer laser beam.

In the excimer laser oscillator containing the optical articles made of fluoride crystal in accordance with the present invention, the optical articles being provided as the prisms or etalons, the wavelength of an excimer laser can be reduced by means of the prisms or the etalons. In other words, the excimer laser can be converted to a single-line laser.

A latent image corresponding to a pattern to be formed can be formed by irradiation of an excimer laser beam onto a photosensitive resist on a substrate through a pattern of a reticle using this exposure device.

Except as otherwise disclosed herein, the various components shown in outline or in block form in the figures are individually well-known and their internal construction and operation are not critical either to the making or using of this invention or to a description of the best mode of the invention.

While the present invention has been described with reference to what are presently considered to be the preferred embodiments, it is to be understood that the invention is not limited to the disclosed embodiments on the contrary, the invention is intended to cover various modifications and equivalent arrangements included within the spirit and scope of the appended claims. The scope of the following claims is to be accorded the broadest interpretation so as to encompass all such modifications and equivalent structures and functions.

What is claimed is:

1. A method of growing a crystal, said method comprising the steps of:
providing a crucible having placed therein (a) a raw material for a crystal to be grown in a crystal-growing furnace and (b) a seed crystal;
generating a predetermined temperature distribution in the crystal growing-furnace, the predetermined temperature distribution including the melting point of the crystal, in a state in which a portion, having the seed crystal placed therein, of the crucible is held at a position in the crystal-growing furnace at which the temperature is lower than the melting point;
moving the crucible in a first direction relative to the temperature distribution after the temperature distribution is generated to melt the unmelted raw material for the crystal; and
moving the crucible in a second direction relative to the temperature distribution to grow the crystal.

2. A method according to claim 1, wherein said step of moving the crucible in a first direction comprises a step of melting of a part of the seed crystal.

3. A method according to claim 1, wherein the crystal to be grown is a fluoride crystal.

4. A method of producing a crystal, said method comprising the steps of:
moving a crucible, in a crystal-growing furnace having generated therein a temperature distribution including the melting point of a crystal to be grown, the crucible having placed therein a raw material for the crystal to be grown, relative to the temperature distribution to grow the crystal;
generating a uniform heat zone of which the temperature is lower than the melting point of the crystal and is substantially uniform, at least in a part of the inside of the crystal-growing furnace, after the crystal-growth is completed;
moving the crucible into the uniform heat zone; and
decreasing the temperature in the uniform heat zone substantially uniformly at a predetermined rate.

5. A method according to claim 4, wherein the crystal to be grown is a fluoride crystal.

6. An apparatus for producing a crystal, said apparatus comprising:
a crucible in which a raw material for a crystal to be grown and a seed crystal are placed;
means for heating to generate a predetermined temperature distribution in the surroundings of said crucible; and
means for supporting and moving the crucible,
wherein said supporting and moving means is movable in a first direction relative to the generated temperature distribution and in a second direction opposite to the first direction.

7. An apparatus according to claim 6, further comprising means for detecting a position of an interface between solid and liquid phases in said crucible,
wherein movement by said supporting and moving means in the first direction is completed before the whole seed crystal is converted into the liquid phase.

8. An apparatus according to claim 6, wherein said crucible has its inner side partitioned into plural stages, and said stages are connected through a connecting hole, respectively.

9. An apparatus according to claim 6, wherein the crystal to be grown is a fluoride crystal.

10. An optical element including a crystal produced using a method according to any one of claims 1 through 5.

11. A semiconductor exposure device comprising:
a wafer stage on which a wafer to be exposed is placed;
an optical illumination-system which guides a light from a light source to a reticle; and
an optical projection-system which guides the light transmitted through the reticle to the wafer on said wafer stage,
wherein at least one of said optical illumination-system and said optical projection-system comprises at least one of optical elements according to claim 10.

12. A method according to claim 1, wherein the first direction is opposite to the second direction.
